(19) United States
(12) Patent Application Publication
(10) Pub. No.: US 2010/0229940 A1
(43) Pub. Date: Sep. 16, 2010

(54) TECHNIQUE FOR PREPARING PRECURSOR FILMS AND COMPOUND LAYERS FOR THIN FILM SOLAR CELL FABRICATION AND APPARATUS CORRESPONDING THERETO

(76) Inventor: Bulent M. Basol, Manhattan Beach, CA (US)

Correspondence Address: PILLSBURY WINTHROP SHAW PITTMAN LLP, P.O. BOX 10500, MCLEAN, VA, 22102, US

(21) Appl. No.: 12/725,328

(22) Filed: Mar. 16, 2010

Related U.S. Application Data
(63) Continuation of application No. 11/462,685, filed on Aug. 4, 2006, now abandoned.
Application No. 11/462,685 is a continuation-in-part of application No. 11/266,013, filed on Nov. 2, 2005, now Pat. No. 7,736,940.
(60) Provisional application No. 60/781,974, filed on Mar. 13, 2006.
(60) Provisional application No. 60/807,703, filed on Jul. 18, 2006.
(60) Provisional application No. 60/729,846, filed on Oct. 24, 2005.
(60) Provisional application No. 60/756,750, filed on Jan. 6, 2006.

(51) Int. Cl. H01L 31/04; H01L 31/0224; H01L 31/18; H01L 31/0272

(52) U.S. Cl. 136/256; 438/95; 257/E31.008; 257/E31.124

(57) ABSTRACT

The present invention advantageously provides for, in different embodiments, improved contact layers or nucleation layers over which precursors and Group IBIIIAVIA compound thin films adhere well and form high quality layers with excellent micro-scale compositional uniformity. It also provides methods to form precursor stack layers, by wet deposition techniques such as electroplating, with large degree of freedom in terms of deposition sequence of different layers forming the stack.

### CLAIM OF PRIORITY

This application claims priority to U.S. Provisional Appln. Ser. No. 60/781,984 filed Mar. 13, 2006, entitled “Technique for Preparing Precursor Layers For Thin Film Solar Cell Fabrication”, to U.S. Provisional Appln. Ser. No. 60/807,703 filed Jul. 18, 2006 entitled “Technique for Preparing Precursor Layers For Thin Film Solar Cell Fabrication”, to U.S. Provisional Appln. Ser. No. 60/729,846 filed Oct. 24, 2005 entitled “Method and Apparatus for Thin Film Solar Cell Manufacture”, and to U.S. Provisional Appln. Ser. No. 60/756,750 filed Jan. 6, 2006 entitled “Precursor Copper Indium, and Gallium for Selenide (Sulfide) Compound Formation”, all of which are expressly incorporated herein in their entirety. This application is also a continuation-in-part of U.S. application Ser. No. 11/266,013 filed Nov. 2, 2005 entitled “Technique and Apparatus for Depositing Layers of Semiconductors for Solar Cell and Module Fabrication”, the contents of which are expressly incorporated herein in their entirety.

### FIELD OF THE INVENTION

The present invention relates to method and apparatus for preparing thin films of semiconductor films for radiation detector and photovoltaic applications.

### BACKGROUND

Solar cells are photovoltaic devices that convert sunlight directly into electrical power. The most common solar cell material is silicon, which is in the form of single or polycrystalline wafers. However, the cost of electricity generated using silicon-based solar cells is higher than the cost of electricity generated by the more traditional methods. Therefore, since early 1970's there has been an effort to reduce cost of solar cells for terrestrial use. One way of reducing the cost of solar cells is to develop low-cost thin film growth techniques that can deposit solar-cell-quality absorber materials on large area substrates and to fabricate these devices using high-throughput, low-cost methods.

Group IBIIIAVIA compound semiconductors comprising some of the Group IB (Cu, Ag, Au), Group IIIA (B, Al, Ga, In, Tl) and Group VIA (O, S, Se, Te, Po) materials or elements of the periodic table are excellent absorber materials for thin film solar cell structures. Especially, compounds of Cu, In, Ga, Se and S which are generally referred to as CIGS(S), or Cu(In,Ga)(S,Se)₂ or CuIn₁₋ₓGaₓ (S_{y}Se_{1-y})ₖ, where 0≦x≦1, 0≦y≦1 and k is approximately 2, have already been employed in solar cell structures that yielded conversion efficiencies approaching 20%. Among the family of compounds, best efficiencies have been obtained for those containing both Ga and In, with a Ga amount in the 15-25%. Absorbers containing more Ga or no In gave lower efficiencies which is believed to be due to the lower carrier lifetimes in Ga-rich materials. Absorbers containing no Ga, on the other hand, have a low bandgap of about 1 eV and also have poor adhesion characteristics to their substrate, limiting their efficiencies. Absorbers containing Group IIIA element Al and/or Group VIA element Te also showed promise. Therefore, in summary, compounds containing: i) Cu from Group IB, ii) at least one of In, Ga, and Al from Group IIIA, and iii) at least one of S, Se, and Te from Group VIA, are of great interest for solar cell applications.

The structure of a conventional Group IBIIIAVIA compound photovoltaic cell such as a Cu(In,Ga,Al)(S,Se,Te)₂ thin film solar cell is shown in FIG. 1. The device 10 is fabricated on a substrate 11, such as a sheet of glass, a sheet of metal, an insulating foil or web, or a conductive foil or web. The absorber film 12, which comprises a material in the family of Cu(In,Ga,Al)(S,Se,Te)₂, is grown over a conductive layer 13 or a contact layer, which is previously deposited on the substrate 11 and which acts as the electrical ohmic contact to the device. The most commonly used contact layer or conductive layer in the solar cell structure of FIG. 1 is Molybdenum (Mo). If the substrate itself is a properly selected conductive material such as a Mo foil, it is possible not to use a conductive layer 13, since the substrate 11 may then be used as the ohmic contact to the device. The conductive layer 13 may also act as a diffusion barrier in case the metallic foil is reactive. For example, foils comprising materials such as Al, Ni, Cu may be used as substrates provided a barrier such as a Mo layer is deposited on them protecting them from Se or S vapors. The barrier is often deposited on both sides of the foil to protect it well. After the absorber film 12 is grown, a transparent layer 14 such as a CdS, ZnO or CdS/ZnO stack is formed on the absorber film. Radiation 15 enters the device through the transparent layer 14. Metallic grids (not shown) may also be deposited over the transparent layer 14 to reduce the effective series resistance of the device. The preferred electrical type of the absorber film 12 is p-type, and the preferred electrical type of the transparent layer 14 is n-type. However, an n-type absorber and a p-type window layer can also be utilized. The preferred device structure of FIG. 1 is called a “substrate-type” structure. A “superstrate-type” structure can also be constructed by depositing a transparent conductive layer on a transparent superstrate such as glass or transparent polymeric foil, and then depositing the Cu(In,Ga,Al)(S,Se,Te)₂ absorber film, and finally forming an ohmic contact to the device by a conductive layer. In this superstrate structure light enters the device from the transparent superstrate side. A variety of materials, deposited by a variety of methods, can be used to provide the various layers of the device shown in FIG. 1.

In a thin film solar cell employing a Group IBIIIAVIA compound absorber, the cell efficiency is a strong function of the molar ratio of IB/IIIA. If there are more than one Group IIIA materials in the composition, the relative amounts or molar ratios of these IIIA elements also affect the properties. For a Cu(In,Ga)(S,Se)₂ absorber layer, for example, the efficiency of the device is a function of the molar ratio of Cu/(In+Ga). Furthermore, some of the important parameters of the cell, such as its open circuit voltage, short circuit current and fill factor vary with the molar ratio of the IIIA elements, i.e. the Ga/(Ga+In) molar ratio. In general, for good device performance Cu/(In+Ga) molar ratio is kept at around or below 1.0. Alternately, if the ratio is larger than 1.0, the film is etched in a solution, such as a cyanide solution, to etch away the excess Cu—Se phase before constructing the solar cell devices. As the Ga/(Ga+In) molar ratio increases, on the other hand, the optical bandgap of the absorber layer increases and therefore the open circuit voltage of the solar cell increases while the short circuit current typically may decrease. It is important for a thin film deposition process to have the capability of controlling both the molar ratio of IB/IIIA, and the molar ratios of the Group IIIA, components in the composition. It should be noted that although the chemical formula is often written as Cu(In,Ga)(S,Se)₂, a more accurate formula for the compound is Cu(In,Ga)(S,Se)ₖ, where k is typically close to 2 but may not be exactly 2. For simplicity we will continue to use the value of k as 2. It should be further noted that the notation “Cu(X,Y)” in the chemical formula means all chemical compositions of X and Y from (X=0% and Y=100%) to (X=100% and Y=0%). For example, Cu(In,Ga) means all compositions from CuIn to CuGa. Similarly, Cu(In,Ga)(S,Se)₂ means the whole family of compounds with Ga/(Ga+In) molar ratio varying from 0 to 1, and Se/(Se+S) molar ratio varying from 0 to 1.

The first technique that yielded high-quality Cu(In,Ga)Se₂ films for solar cell fabrication was co-evaporation of Cu, In, Ga and Se onto a heated substrate in a vacuum chamber. However, low materials utilization, high cost of equipment, difficulties faced in large area deposition and relatively low throughput are some of the challenges faced in commercialization of the co-evaporation approach.

Another technique for growing Cu(In,Ga)(S,Se)₂ type compound thin films for solar cell applications is a two-stage process where metallic components of the Cu(In,Ga)(S,Se)₂ material are first deposited onto a substrate, and then reacted with S and/or Se in a high temperature annealing process. For example, for CuInSe₂ growth, thin layers of Cu and In are first deposited on a substrate and then this stacked precursor layer is reacted with Se at elevated temperature. If the reaction atmosphere also contains sulfur, then a CuIn(S,Se)₂ layer can be grown. Addition of Ga in the precursor layer, i.e. use of a Cu/In/Ga stacked film precursor, allows the growth of a Cu(In,Ga)(S,Se)₂ absorber.

Sputtering and evaporation techniques have been used in prior art approaches to deposit the layers containing the Group IB and Group IIIA components of the precursor stacks. In the case of CuInSe₂ growth, for example, Cu and In layers were sequentially sputter-deposited on a substrate and then the stacked film was heated in the presence of gas containing Se at elevated temperature for times typically longer than about 30 minutes, as described in U.S. Pat. No. 4,798,660. More recently U.S. Pat. No. 6,048,442 disclosed a method comprising sputter-depositing a stacked precursor film comprising a Cu—Ga alloy layer(s) and an In layer to form a Cu—Ga/In stack on a metallic back electrode layer and then reacting this precursor stack film with one of Se and S to form the absorber layer. U.S. Pat. No. 6,092,669 described sputtering-based equipment for producing such absorber layers. Such techniques may yield good quality absorber layers and efficient solar cells, however, they suffer from the high cost of capital equipment, and relatively slow rate of production. Also physical vapor deposition (PVD) techniques such as sputtering and evaporation, although flexible in changing the deposition sequence of the elements forming a metallic stack, have certain drawbacks in terms of ability to form stacks with layers of un-alloyed, pure materials as will be discussed later.

One prior art method described in U.S. Pat. No. 4,581,108 utilizes a low cost electrodeposition approach for metallic precursor preparation. In this method a Cu layer is first electrodeposited on a substrate covered with Mo. This is then followed by electrodeposition of an In layer and heating of the deposited Cu/In stack in a reactive atmosphere containing Se to obtain CIS. In later work an electrodeposition sequence of Cu/In/Ga was also reported to obtain CIGS films. Although low-cost in nature, both of these techniques were found to yield CIS films with poor adhesion to the Mo contact layer. In a publication (“Low Cost Thin Film Chalcopyrite Solar Cells”, Proceedings of 18^{th} IEEE Photovoltaic Specialists Conf., 1985, p. 1429) electrodeposition and selenization of Cu/In and Cu/In/Ga layers were demonstrated for CIS and CIGS growth. One problem area was identified as peeling of the compound films during solar cell processing. Later, in another reference (“Low Cost Methods for the Production of Semiconductor Films for CIS/CdS Solar Cells”, Solar Cells, vol. 21, p. 65, 1987) researchers studied the cross-section of Mo/CuInSe₂ interface obtained by the above-mentioned method and found the CuInSe₂ to have poor adhesion to the Mo contact layer.

As mentioned above Mo, is the most commonly used ohmic contact material (or conductive layer 13 in FIG. 1) in CIS or CIGS type solar cells. The conductive layer 13 or contact layer of FIG. 1 has multiple functions and must meet certain criteria. Contact layer must be relatively inert not to react extensively with Se, Te or S or the CIS or CIGS layers themselves. It has to function as a barrier for impurity diffusion from the substrate into the CIS or CIGS layer or protect the substrate with reaction with Se, S or Te. It has to make a good ohmic contact to the solar cell and provide good optical reflection so that, especially in very thin device structures, photons reaching the back of the device get reflected and provide more light-generated carriers to be collected. Molybdenum was found to provide these qualities to a large extent and therefore has been used widely as the contact layer or ohmic contact material, although some researchers used Gold (Au) also in their experiments (see for example, C. Huang et al, Solar Energy Materials and Solar Cells, vol: 82, p. 553, (2004)). In a recent publication, Orgassa et al evaluated Tungsten (W), Mo, Tantalum (Ta), Niobium (Nb), Chromium (Cr), Vanadium (V), Titanium (Ti) and Manganese (Mn) as back contact to CIGS solar cells for the purpose of identifying a material that would yield the most stable and repeatable performance (see; Thin Solid Films, vol: 431, p: 387 (2003)). They found that W, Mo, Ta and Nb were inert during the CIGS deposition process, which was a co-evaporation method. Other metals reacted with Se and some were totally consumed into the growing layer during the CIGS film growth. Researchers concluded that W, Ta and Nb could replace Mo as the ohmic contact metal to CIGS solar cells. U.S. Pat. No. 6,307,148 described a method wherein an interfacial layer of Palladium (Pd) or Platinum (Pt) was coated over the Mo contact layer before the formation of a Cu-rich (Cu to Group IIIA metal ratio higher than 1.6) copper indium or copper indium gallium sulfide or selenide compound layer mixed with Cu-sulfide or copper selenide phases. This mixed phase material was then etched in a KCN solution to etch away the Cu-sulfide or Cu-selenide phases, leaving beside the solar-cell-grade copper-indium selenide or sulfide layer. It was stated, in the absence of Pd or Pt interfacial layers, the KCN etching step led to film peeling problems if the Cu to Group IIIA ratio was larger than 1.6. With the Pt or Pd interfacial layers, films did not peel after the KCN etching step even if their Cu to Group IIIA ratios were larger than 1.6. U.S. Pat. No. 5,028,274 used a Tellurium (Te) interfacial layer to enhance adhesion of CIS films to the contact layers which were selected from the group comprising Mo, W, Ta, Ti, Au and Titanium Nitride (TiN). U.S. Pat. No. 4,915,745 cited Mo, W, Au, Nickel (Ni) and Nickel-phosphide (Ni—P) as possible contact layers to CIGS type solar cells. In U.S. Pat. No. 5,695,627 researchers electroplated Cu—In—Se—S using as contact layers metals from the group of Mo, Ti, Cr, and Pt. U.S. Pat. No. 5,676,766 listed Cr, Ti, Ta and TiN as interlayers to improve adhesion. In U.S. Pat. No. 5,626,688 Mo, TiN, Pd and Pt are mentioned as contacts to CIS type films. In U.S. Pat. No. 5,501,786 Mo, TiN and Zirconium nitride (ZrN) were used as base conductors over which layers comprising Se particles were plated.

Wet processing techniques such as electrodeposition and electroless deposition, although lower cost than the PVD approaches such as evaporation and sputtering, have their unique challenges. For example, electrodeposition or electroplating techniques are much more substrate-sensitive compared to the PVD techniques. In a PVD process metal A may be evaporated or sputter deposited on metal B and the deposition sequence may be reversed at will, i.e. metal B may be deposited on metal A or stacks such as A/B/A/B or B/A/B/A may be formed. In an electrodeposition process, however, there have been limitations in forming metallic stacks comprising various different metals. For example, as reviewed above, prior art methods electroplated Cu, In and optionally Ga to form Cu/In and Cu/In/Ga stacks on Mo coated substrates for the fabrication of Mo/CIS and Mo/CIGS structures, which were then used for solar cell fabrication. One of the reasons for selecting Cu/In and Cu/In/Ga electrodeposition sequence was the fact that Cu, In and Ga have very different standard plating potentials. The molar standard electrode potentials of Cu/Cu²⁺, In/In³⁺ and Ga/Ga³⁺ metal/ion couples in aqueous solutions are about +0.337 V, −0.342 V, and −0.52 V, respectively. This means that Cu can be plated out at low negative voltages. For In deposition, on the other hand, larger negative voltages are needed. For Ga deposition, which is challenging due to hydrogen evolution, even larger negative voltages are required. Therefore, to form a stack containing Cu, In and Ga, Cu was typically electroplated first. This was then followed by deposition of In and then Ga so that while plating the second metal over the first metal, the first metal does not dissolve into the electrolyte of the second metal. Therefore, prior-art methods have employed Cu/In/Ga stacks electroplated in that order. However, after selenization such stacks yielded compound layers with poor morphology and poor adhesion to the base or the Mo coated substrate as was discussed before.

Other attempts to use electrodeposited precursors for the formation of Cu(In,Ga)Se₂ layers included electroplating of a Cu—Ga film followed by electroplating of a Cu—In—Se film thereby forming a Cu—Ga/Cu—In—Se stack; and annealing the stack at 600 C (Friedfeld et al., Solar Energy Materials and Solar Cells, vol: 58, p: 375, 1999). Zank et al. (Thin Solid Films, vol: 286, p: 259, 1996) sputter deposited a Cu—Ga alloy film on a glass/Mo substrate. They then electroplated, from a single bath, an In—Ga film, forming a Cu—Ga/In—Ga stack. This stack was then reacted with Se to form the compound. This approach would not be low cost because preparation of Cu—Ga alloy sputtering targets is in itself expensive and utilization of the target material is very low (typically lower than 40%) in a sputtering approach. Ganchev et al. electrodeposited a Cu—In—Ga precursor film from a single bath and obtained Cu(In,Ga)Se₂ layer after selenizing this precursor layer (Thin Solid Films, vol: 511-512, p: 325, 2006).

Macro and micro-scale non-uniformities in the thickness and morphology of sub-layers in a precursor film including Cu, In, and/or Ga cause morphological and compositional non-uniformities in the CIGS(S) absorber after Cu, and/or In and/or Ga are reacted with a Group VIA material such as Se and/or S forming the CIGS(S) absorber. This topic has been discussed in detail in our U.S. Patent Application Publication No. 2005/0202589 (Sep. 15, 2005) and U.S. Patent Application Publication No. 2006/0121701 (Jun. 8, 2006).

As the brief review above demonstrates, there is still need to develop alternative ohmic contact materials to CIGS type solar cells for better mechanical, structural, compositional and electrical properties of the CIGS type absorber layers. There is also need to provide low cost electrodeposition approaches with flexibilities similar to those of the more expensive PVD techniques in forming various metallic precursor stacks comprising Cu, In and Ga together, since precursors containing only Cu and In or only Cu and Ga would provide CuIn(S,Se)₂ or CuGa(S,Se)₂ absorber layers which yield solar cells with efficiencies much lower than 20% which has been demonstrated for Cu(In,Ga)(S,Se)₂ material. There is also need for electroplated precursor films that, when reacted with at least one Group VIA element, yields CIGS(S) type absorber layers that adhere well to their substrate or base.

### SUMMARY OF THE INVENTION

The present invention relates to a technique for preparing precursor films and compound layers for thin film solar cell fabrication and an apparatus corresponding thereto.

The present invention includes a variety of different embodiments.

In one embodiment, the technique for preparing precursor films and compound layers for thin film solar cell fabrication includes forming an absorber layer by depositing a set of distinct layers over a top surface of the conductive layer, the set of distinct layers including at least four layers, with two of the layers being a pair of non-adjacent layers made of one of Cu, In and Ga, and the other two layers being made of the remaining two of the Cu, In and Ga, and then treating the set of distinct layers to form the absorber layer.

In another embodiment, a Cu(In,Ga)(Se,S)₂ absorber layer is formed by applying, over a sheet-shaped base, a conductive layer comprising at least one of Mo, Ru, Ir and Os; electrodepositing discrete layers in sequence to form a precursor stack over the conductive layer, each discrete layer substantially comprising one of Cu, In and Ga, and wherein at least one discrete layer substantially comprising Cu is electrodeposited using a Cu electrolyte over another discrete layer substantially comprising one of In and Ga; and reacting the precursor stack with at least one of Se and S.

In another embodiment, solar cell fabrication includes forming a conductive layer over a sheet-shaped base; forming a semiconductor absorber layer over a surface of the conductive layer, wherein the semiconductor absorber layer comprises a Group VIA material; and forming an additional layer over the absorber layer, wherein one of the steps of forming the conductive layer and forming the additional layer includes at least one of Ru, Ir, and Os in the conductive layer and the additional layer, respectively. When a substrate type solar cell is fabricated, the at least one of Ru, Ir, and Os will exist in the conductive layer and the additional layer is transparent, whereas in a superstrate type solar cell, the at least one of Ru, Ir, and Os will exist in the additional layer and the substrate and the conductive layer are both transparent.

A solar cell, according to one embodiment of the invention, includes a sheet-shaped substrate; a conductive layer disposed over the sheet shaped substrate; an absorber layer disposed over the conductive layer, wherein the absorber layer includes at least one Group IB material, at least one Group IIIA material, and at least one Group VIA material; and an additional layer disposed over the absorber layer, wherein one of the conductive layer and the additional layer includes at least one of Ru, Os, and Ir. When the solar cell is of the substrate type, the at least one of Ru, Ir, and Os will exist in the conductive layer and the additional layer is transparent, whereas in a superstrate type solar cell, the at least one of Ru, Ir, and Os will exist in the additional layer and the substrate and the conductive layer are both transparent.

### BRIEF DESCRIPTION OF THE DRAWINGS

These and other aspects and features of the present invention will become apparent to those of ordinary skill in the art upon review of the following description of specific embodiments of the invention in conjunction with the accompanying figures, wherein:

FIG. 1 is a cross-sectional view of a solar cell employing a Group IBIIIAVIA absorber layer.

FIG. 2A is a cross-sectional view of a precursor layer deposited on the surface of a preferred contact layer.

FIG. 2B is a cross-sectional view of a precursor layer deposited on the surface of a nucleation layer.

FIG. 3A shows a structure comprising a CIGS(S) absorber film on a preferred contact layer.

FIG. 3B shows a structure comprising a CIGS(S) absorber film on a nucleation layer.

### DETAILED DESCRIPTION

As described in the discussion of prior art, the PVD techniques have the ability to alter the deposition sequence of Cu, In and Ga during the preparation of metallic precursors for the formation of CIGS type solar cell absorber layers by two-stage processes. In the electroplating approaches this has not been possible due to the sensitivity of the technique to the surface on which electroplating process is performed. Present invention overcomes the shortcomings of prior art electroplating techniques and provides more flexibility to formation of various metallic stacks comprising Cu, In and Ga and also addresses the issues of adhesion, yield, manufacturability and micro-scale morphological, structural and compositional uniformity.

In one embodiment, a complex copper electroplating solution is used with the ability to deposit good quality, small-grained and continuous copper films over materials comprising Mo, W, Ta, Ruthenium (Ru), Rhodium (Rh), Iridium (Ir), Osmium (Os), Zirconium (Zr), Rhenium (Re), Scandium (Sc), Yitrium (Y), Lanthanum (La) and other elemental components of the metallic stack, i.e. In and Ga. The copper complex bath may contain citrate (such as trisodium citrate), triethanolamine (TEA), ethylene diamine tetra acetic acid (EDTA), nitrilo-3 acetic acid (NTA), tartaric acid, acetate and other known copper complexing agents in addition to copper from a copper salt such as copper sulfate, copper chloride, copper nitrate, copper acetate and the like, and a solvent which may comprise water, alcohol, ethylene glycol, glycerol etc. The pH of the copper plating solution is higher than 3, preferably higher than 7. The plating current density of Cu from the complex copper electroplating solution is in the range of 0.1-30 mA/cm², preferably in the range of 0.5-20 mA/cm², more preferably in the range of 1-10 mA/cm². It should be noted that the ability of the complex copper plating solution to deposit continuous films at low current densities allows thickness control for very thin layers such as layers with a thickness of 5-50 nm. Also complexing the copper increases its plating potential to high negative values (for example, more negative than −0.8V with respect to a calomel reference electrode) compared to the low positive or low negative values, such as up to about −0.5 V for aqueous acidic solutions. The high negative voltages in complex copper baths break down any native oxide or other passivation layer on the base material (such as Mo, In or Ga) over which Cu is plated and improves nucleation. Prior art acidic copper electrolytes such as the copper sulfate solutions used in U.S. Pat. No. 4,581,108 yield continuous Cu layers on Mo surface only at high current densities, which are typically higher than about 30 mA/cm², preferably higher than 50 mA/cm². The exemplary Cu plating step in U.S. Pat. No. 4,581,108 used a current density of 80 mA/cm². It should be appreciated that such high current densities cause thickness non-uniformities on large area substrates due to large I-R voltage drops and also make it unpractical to dependably control the thicknesses of layers with thicknesses smaller than 200 nm. In prior art methods, a single Cu layer with a thickness of about 200 nm was used in the precursor stack. As will be described more fully below, the present invention offers the flexibility of forming metallic stacks wherein, Cu, In and Ga may be distributed throughout the stack at various locations. This means that the 200 nm thick Cu layer may be distributed within the stack in the form of Cu sub-layers with thicknesses much smaller than 200 nm. Accurate control of such small thicknesses requires plating current densities much smaller than prior art 80 mA/cm².

The following examples will demonstrate the flexibility offered by using complex copper solutions for the formation of various metallic stacks for CIGS type absorber fabrication. In these examples, the following exemplary solutions are used for the various deposition steps. A) Copper deposition solution (SOLCu) comprises 0.1 M copper sulfate-penta hydrate, 0.5 M trisodium citrate and a pH of 11, B) Ga deposition solution (SOLGa) comprises 1M gallium chloride in glycerol and a pH of 2, and C) In deposition solution (SOLIn) is an In sulfamate solution purchased from Indium Corporation of America. This solution has a pH in the range of about 1-3, typically about 1.5.

For a typical CIGS solar cell, the absorber layer is in the range of 1-3 um thick, thinner layers being preferable because of lower materials cost. An absorber thickness of 2-2.5 um requires a copper layer thickness of about 200 nm, Ga layer thickness of about 92 nm and In layer of about 368 nm for a Cu/(In+Ga) molar ratio of about 0.9, and Ga/(Ga+In) molar ratio of about 25%. Therefore, in the examples below stacks with total Cu, In and Ga thicknesses of about 200 nm, 100 nm and 400 nm, respectively are electrodeposited to approximate the desired values given above.

### Example 1

### Cu/Ga/Cu/In Stack Formation

A glass/Mo base is used in the experiment. Mo is sputter deposited to a thickness of about 700 nm on the glass sheet. Then SOLCu is employed to electroplate 150 nm thick Cu sub-layer over the Mo surface at a current density of 5 mA/cm². The resulting Cu sub-layer is uniform and smooth with 3-5 nm surface roughness. A 100 nm thick Ga layer is deposited on the Cu sub-layer using SOLGa at a current density of 10 mA/cm². A smooth and shiny silver-colored layer is obtained. SOLCu solution is utilized again to deposit 50 nm thick Cu sub-layer over the Ga layer at a current density of 5 mA/cm². No Ga is lost into the SOLCu during Cu plating since the plating potential of Cu with respect to a calomel electrode placed into the solution was measured to be in the (−1 to −2 V) range. Such high cathodic potential protects the Ga layer from dissolving and also allows deposition of a small-grained and continuous Cu sub-layer on the Ga surface. After the formation of the 50 nm thick Cu sub-layer over the 100 nm thick Ga layer, SOLIn is used at 15 mA/cm² current density to form a 400 nm thick In layer.

### Example 2

### Cu/Ga/Cu/In/Cu Stack Formation

A glass/Mo base is used. Mo is sputter deposited to a thickness of about 700 nm on the glass sheet. Then SOLCu is employed to electroplate 150 nm thick Cu sub-layer over the Mo surface at a current density of 5 mA/cm². The resulting Cu sub-layer is uniform and smooth with 3-5 nm surface roughness. A 100 nm thick Ga layer is deposited on the Cu sub-layer using SOLGa at a current density of 10 mA/cm². A smooth and shiny silver-colored layer is obtained. SOLCu solution is utilized again to deposit 10 nm thick Cu sub-layer over the Ga layer at a current density of 5 mA/cm². After the formation of the 10 nm thick Cu sub-layer over the 100 nm thick Ga layer, SOLIn is used at 15 mA/cm² current density to form a 400 nm thick In layer. Over the In layer, another Cu sub-layer is plated using SolCu to a thickness of 40 nm. No In is lost into the SOLCu during Cu plating since the plating potential of Cu with respect to a calomel electrode placed into the solution was measured to be in the (−1 to −2 V) range. Such high cathodic potential protects the In layer from dissolving and also allows deposition of a small-grained and continuous Cu sub-layer on the In surface.

### Example 3

### Cu/In/Cu/Ga Stack Formation

A glass/Mo base is used. Mo is sputter deposited to a thickness of about 700 nm on the glass sheet. Then SOLCu is employed to electroplate 150 nm thick Cu sub-layer over the Mo surface at a current density of 5 mA/cm². The resulting Cu sub-layer is uniform and smooth with 3-5 nm surface roughness. A 400 nm thick In layer is deposited on the Cu sub-layer using SOLIn at a current density of 15 mA/cm². SOLCu solution is utilized again to deposit 50 nm thick Cu sub-layer over the In layer at a current density of 5 mA/cm². No In is lost into the SOLCu during Cu plating since the plating potential of Cu with respect to a calomel electrode placed into the solution is measured to be in the (−1 to −2 V) range. Such high cathodic potential protects the In layer from dissolving and also allows deposition of a small-grained and continuous Cu layer on the In surface. After the formation of the 50 nm thick Cu sub-layer over the 400 nm thick Ga layer, SOLGa is used at 5 mA/cm² current density to form a 100 nm thick Ga layer.

### Example 4

### Cu/In/Cu/Ga/Cu Stack Formation

A glass/Mo base is used. Mo is sputter deposited to a thickness of about 700 nm on the glass sheet. Then SOLCu is employed to electroplate 150 nm thick Cu sub-layer over the Mo surface at a current density of 5 mA/cm². The resulting Cu sub-layer is uniform and smooth with 3-5 nm surface roughness. A 400 nm thick In layer is deposited on the Cu sub-layer using SOLIn at a current density of 15 mA/cm². SOLCu solution is utilized again to deposit 20 nm thick Cu sub-layer over the In layer at a current density of 5 mA/cm². No In is lost into the SOLCu during Cu plating since the plating potential of Cu with respect to a calomel electrode placed into the solution is measured to be in the (−1 to −2 V) range. Such high cathodic potential protects the In layer from dissolving and also allows deposition of a small-grained and continuous Cu sub-layer on the In surface. After the formation of the 20 nm thick Cu sub-layer over the 400 nm thick In layer, SOLGa is used at 5 mA/cm² current density to form a 100 nm thick Ga layer. Over the Ga layer a 30 nm thick Cu sub-layer is formed using the SOLCu solution at a current density of 5 mA/cm².

It should be noted that the metallic precursor stacks discussed in the above examples may have even more number of sub-layers. For example, the In layer may be divided into two or more In sub-layers. Similarly, Ga layer may be divided into two or more Ga sub-layers that may be distributed within the metallic stack. Although up to three Cu sub-layers are described in the examples above, more Cu sub-layers may also be formed and distributed within the electroplated metallic stack. By distributing Cu, In and Ga in electroplated metallic precursors several benefits may be obtained. One of these benefits is the easy intermixing/reaction between the thin sub-layers distributed within the stack during the reaction step. Another benefit is improved adhesion after reaction with a Group VIA material. For example, as opposed to the prior art electroplated Cu/In/Ga precursor stack, the electroplated Cu/Ga/Cu/In precursor stack of the present invention brings the Ga closer to the Mo interface. This improves adhesion of the compound to the Mo surface after reaction with Se and/or S and formation of the CIGS(S) compound layer. The Ga may be brought even closer to the contact layer interface by for example, reducing the thickness of the Cu sub-layer deposited on the contact layer to a range of 2-50 nm and then increasing the thickness of the Cu sublayer deposited over the Ga layer (see examples 1 and 2). In some RTP approaches a Se layer is deposited over a metallic precursor layer comprising Cu, In and Ga and then the whole structure is heated to elevated temperatures to react Se with the Cu, In and Ga and form CIGS. In such an approach, if the prior art electroplated Cu/In/Ga stack is employed and a Se film is deposited onto the Ga surface to form a Cu/In/Ga/Se structure, the morphology of the CIGS layer may be rough and non-uniform. The reason is the fact that Ga is a low melting metal with a melting temperature of less than 30 C. The In/Ga interface within this stack has even lower melting temperature since the eutectic composition of 16% In-84% Ga has a melting temperature of about 15.7 C. Therefore, even before any reaction between Se and the metallic stack initiates, the near-surface region of the metallic stack melts and causes balling. As the temperature is raised to react Se with the metallic stack situation may get even worse and rough morphology and compositional non-uniformity may result. In the present electroplated stacks a higher melting temperature layer, such as an In layer (Example 1) or a Cu layer/sub-layer (Examples 2 and 4) may be placed at the top of the metallic stack. Such higher melting phase at the surface of the stack reduces phenomenon of balling and improves the resulting morphology and the micro-scale compositional uniformity. The thickness of the Cu cap on the metallic stack (Examples 2 and 4) may be varied at will and may be in the range of 2-200 nm, preferably in the range of 5-50 nm. It should be noted that a metallic precursor stack comprising Cu, In and Ga, wherein, the Ga and In are separated from each other by a Cu layer or sub-layer has benefits. In stacks comprising material sequences of Ga/Cu/In, Cu/Ga/Cu/In, In/Cu/Ga, and/or Cu/In/Cu/Ga, the Ga and In phases are separated by a Cu phase and therefore do not form the low melting Ga—In region at their interface as mentioned above. Cu, in this case, acts as a full or partial barrier between Ga and In, slowing down or stopping intermixing between Ga and In and formation of low melting (below 30 C) compositions during or after fabrication of the precursor stacks.

Electroplated metallic stacks have certain properties that are not provided by stacks obtained by PVD. As discussed before, PVD has the flexibility of changing the deposition sequence of Cu, In and Ga. However, metallic precursors obtained by PVD may not end up to be the intended stacks. This is because PVD methods are relatively high energy. In other words material arriving onto the substrate comes with high energy that causes alloying between the depositing species and the species that were already on the substrate. For example, when Cu is deposited over In or Ga layers by evaporation or sputtering, what is obtained may not be In/Cu or Ga/Cu stacks but layers comprising various alloys of these materials along with elemental phases, since In and Ga have low melting temperatures and arriving Cu species have high enough energy to cause intermixing between In and/or Ga and Cu. Wet techniques such as electroplating and electroless plating, when carried out at low temperature, such as at a temperature below the melting point of species depositing or species already on the substrate, have the unique ability to yield stacks with layers and/or sub-layers with well defined phases that can be obtained repeatably. For example, a Cu/Ga/Cu/In stack electroplated at 20 C is substantially non-alloyed, as explained before, due to the low temperature nature of electroplating and due to the presence of a Cu sub-layer between the Ga and In sub-layers. This way the starting phase content of the precursor is repeatable and known. Having a low-melting pure phase such as Ga or In buried in a precursor stack has certain benefits, especially for the case of rapid thermal processing during reaction with the Group VIA materials such as Se, S or Te. One of these benefits is to have an elemental liquid phase within the stack during the reaction period which gives the forming CIGS(S) compound a liquid environment to grow in. It is known that crystals or grains growing in a melted or liquid environment grow larger due to the high mobility of grain boundaries in such liquid flux. Large grain absorber material, such as CIGS(S) is one of the key ingredients of making high efficiency solar cells. If Cu/Ga/Cu/In stack was substantially alloyed, melting temperature of the alloys would be higher than the melting temperatures of the elemental phases of Ga and In.

Another benefit of the electroplated stacks with well defined pre-determined phase content is the ability they offer to control the chemical reaction paths. For example, consider an electroplated metallic Cu/Ga/Cu/In stack. Let us assume that a Se layer is deposited over this stack by a PVD process or electroplating or electroless deposition etc. to obtain a Cu/Ga/Cu/In/Se structure. When this structure is heated, reaction of In and Se and formation of In-selenide species may be promoted. These species may then further react with Cu, Ga, and In containing species and Se to form the final compound. Alternately, if the starting structure is Cu/Ga/Cu/In/Cu/Se early reaction of Cu and Se and formation of Cu-selenide species may be promoted since Se and Cu are in intimate physical contact. Cu-selenide species may then further react with Cu, In, Ga species and Se to form the final compound. Since thermodynamics as well as kinetics determine optimum reaction path ways, by changing the order of Cu, In and Ga within the metallic stack, the most favorable order may be determined that yields the fastest reaction, largest grain size, best electrical characteristics etc. As discussed before, PVD methods do not yield such well defined stacks. Rather they yield stacks which are already partially or fully reacted or alloyed.

In the examples above, each layer or sub-layer within the metallic stack is made of a pure element, i.e. Cu, In or Ga. It should be noted that, it is within the scope of the invention to include alloys and/or mixtures in the metallic stack. For example, at least one of the Cu sub-layers in the above examples may be replaced with a Cu—Ga alloy or mixture sub-layer, or a Cu—In alloy or mixture sub-layer. Similarly, any Ga or In layer may be replaced with an In—Ga mixture or alloy sub-layer. In cases where at least one layer or sub-layer is replaced with an alloy or mixture sub-layer or layer, the thicknesses of the rest of the layers and sub-layers within the stack may be adjusted to keep the overall Cu/(Ga+In) and Ga/(Ga+In) molar ratios at the desired levels.

It should be noted that in the exemplary stacks discussed so far a Cu sub-layer is first electroplated on the base and forms a repeatable surface over which an In layer or a Ga layer is electroplated. Then, another Cu sub-layer is electroplated using the complex solution forming a well-behaved Cu surface over which the stack may continue to be built by depositing another In and/or Ga sub-layer over the Cu sub-layer. Although the preferred method is to provide a Cu surface for the electrodeposition of an In and/or Ga layer, in some experiments we observed that a Cu/Ga/In stack may also be formed by plating In over the Ga surface directly. Having In coated over the low melting Ga surface and building a Cu/Ga/In stack has relative benefits in avoiding the morphology problems associated with the prior art Cu/In/Ga stack as explained before. In other words it is better to have a higher melting point In at the surface of the stack rather than having low melting Ga surface exposed to the Group VIA element during compound formation. This is further discussed in Provisional Patent Application Ser. No. 60/729,846 filed Oct. 24, 2005, entitled “Method and Apparatus for Thin Film Solar Cell Manufacturing”, the contents of which are expressly incorporated by reference herein. In case a Cu sub-layer is provided in the stack over which an In or Ga sub-layer or layer is electroplated, the thickness of the Cu sub-layer may be as little as an atomic layer, just to convert the surface of the underlying layer comprising Ga and/or In into Cu. However, a thickness of at least 2 nm is preferred for this Cu sub-layer.

In the above examples, the widely used glass/Mo structures were employed as the base for electrodeposited stack layers. It is also possible to replace the glass substrate with a conductive or non-conductive sheet or foil such as a polyimide, stainless steel, aluminum (Al), aluminum alloy, Ti or Mo foil and deposit the contact layer Mo over the foil substrate. Since electrodeposition is surface sensitive, the nature of the contact layer over which electrodeposition is performed is especially important for preparing a metallic stack comprising Cu, In and Ga using electroplating.

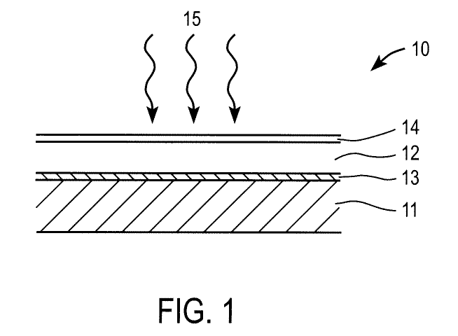

Use of a complex Cu plating bath in the present invention allows plating of Cu on almost all conductive surfaces such as Mo, Ga and In surfaces, and provides the flexibilities in the formation of the various metallic stacks discussed so far. Present inventor found that even more flexibility in the deposition sequence of Cu, In and Ga may be achieved if a conductor from the preferred group of materials is used in the contact layer of the device structure of FIG. 1 or if the contact layer is further coated or replaced with a film comprising at least one element from the preferred group as will be discussed next.

The elements of the preferred group are Ruthenium (Ru), Iridium (Ir), Osmium (Os), Rhodium (Rh), Zirconium (Zr), Hafnium (Hf), Rhenium (Re), Scandium (Sc), Yitrium (Y), and Lanthanum (La). Out of these elements, three of them, namely Ru, Ir and Os are the most preferred materials as will be described later.

When used as contact layers, films of the preferred group elements may replace the contact layer 13 of FIG. 1. Alternately, many other materials such as Cu, Mo, Al, Ti, Ta, W etc. may be alloyed or mixed with at least one of the metals belonging to the preferred group and alloys or mixtures thus formed may be used for the formation of the contact layer 13. Alloys may also be formed by alloying at least two of the elements from the preferred group. The metals of the preferred group have good diffusion barrier characteristics. They are relatively inert. When alloyed with other materials they increase the chemical inertness and strength of the other materials. Furthermore, elements of the preferred group and alloys comprising them offer a unique benefit in the formation of precursor stacks by wet techniques such as electrodeposition and electroless deposition because these materials, especially those from the most preferred group, provide better nucleation capability to the material electroplated on them. Although Cu may be electroplated directly on Mo layer using the complex electrolytes described before, Cu deposition is even better on the metals of the preferred group in terms of adhesion and morphology. Furthermore, if In or Ga electrodeposition is attempted directly on Mo, Ti or Ta surfaces, for example, without depositing a Cu sub-layer first (as described in Examples 1 through 4), powdery and discontinuous layers are observed. By replacing the Mo contact layer with a layer of Ru, Ir or Os, or depositing a thin nucleation layer (such as 2-100 nm thick Ru, Ir or Os layer) over the Mo surface however, both In and Ga may be directly electroplated on the nucleation layer. Therefore, when the base on which electroplating is performed comprises an element from the preferred group or an alloy comprising at least one element from the preferred group, electroplating of a large number of different stacks is possible. Examples of such metallic stacks include (in addition to the stacks already mentioned in the previous examples) but are not limited to In/Cu/Ga, In/Cu/Ga/Cu, In/Cu/Ga/In, In/Cu/In/Ga, In/Cu/Ga/In/Cu, In/Cu/In/Ga/Cu, Ga/Cu/In, Ga/Cu/In/Cu, Ga/Cu/In/Ga, Ga/Cu/Ga/In, Ga/Cu/In/Ga/Cu, Ga/Cu/Ga/In/Cu, Ga/In/Cu, Ga/In/Cu/Ga, Ga/In/Cu/In, Ga/In/Cu/Ga/Cu, Ga/In/Cu/In/Cu, Ga/In/Ga/Cu, In/Ga/Cu, In/Ga/Cu/In, In/Ga/Cu/Ga/Cu, and In/Ga/Cu/In/Cu. It is also possible to build other stacks comprising any one of the above structures, such as stacks that can be obtained by adding a Cu sub-layer before the first element in the stacks above. If the material to be grown is copper gallium sulfide or selenide, In may be left out of the stack. The metals in the preferred group or their alloys may be deposited by PVD techniques such as evaporation and sputtering, by chemical vapor deposition, atomic layer deposition, electrodeposition or electroless deposition. Electrodeposited Ru and Ir are especially suited well for a process where Cu, Ga and In are also electrodeposited.

In examples 1-4 above, a Cu sub-layer was deposited over the Mo contact layer. This was then followed by deposition of stacks comprising In, Ga and Cu. It should be pointed out here that when the Cu sublayer was deposited over a layer comprising at least one of Ru, Ir and Os, electrodeposition efficiency of In and/or Ga over this Cu sub-layer was found to be higher than their electrodeposition efficiency over a Cu sub-layer deposited on a Mo layer, despite the fact that one would think the Cu sub-layer would shield the underlying metal from the depositing Ga and/or In species. For example, electrodeposition efficiency of Ga and/or In on the Cu sub-layer of a Ru/Cu stack was found to be 70-100%, whereas, electrodeposition efficiency of Ga and/or In on the Cu sub-layer of a Mo/Cu stack was 40-80%, depending on current density, stirring rate etc. Electrodeposition efficiency represents the percentage of deposition current that result in material deposition. An efficiency of 80%, for example, means 80% of the deposition current resulted in material deposition whereas 20% is wasted, typically causing hydrogen gas generation at the cathode. The above examples demonstrate that presence of material(s) from the most preferred group (Ru, Ir, Os) on a surface of a base or substrate improves the electrodeposition efficiencies of Cu, In and Ga on the surface. Additionally, presence of a surface comprising at least one of Ru, Os and Ir increases plating efficiencies of In, Cu, and Ga on a sub-layer already deposited on the surface, the sub-layer comprising at least one of Cu, In and Ga. It is expected that same phenomenon would be applicable to Se and/or S electrodeposition or to co-deposition of Se and/or S with at least one of Cu, In and Ga.

Macro and micro-scale non-uniformities in the thickness and morphology of sub-layers in a precursor film comprising at least one of Cu, In and Ga, cause morphological and compositional non-uniformities in the CIGS(S) absorber after Cu, and/or In, and/or Ga are reacted with a Group VIA material such as Se and/or S forming the CIGS(S) absorber. This topic has been discussed in detailed in U.S. Patent Application Publication No. 2005/0202589 (Sep. 15, 2005) and U.S. Patent Application Publication No. 2006/0121701 (Jun. 8, 2006) mentioned previously, and the contents of which are expressly incorporated by reference herein. Thickness non-uniformities and morphological and compositional non-uniformities in Group IBIIIAVIA compound thin films may result from poor wetting of the substrate surface by the depositing species and therefore may be minimized or eliminated by careful selection of the chemical composition of the surface on which a Group IB material and/or a Group IIIA material and/or a Group VIA material is deposited. For example, Cu, In, Ga and Se nucleate well on materials from the most preferred group, thus forming small-grain, smooth and well adhering layers. This better nucleation property is universal for all deposition techniques. In other words, Cu, In, Ga layers nucleate well on Ru, Ir and Os surface when they are deposited by electroplating, evaporation, sputtering, chemical vapor deposition, ink deposition, plasma spraying, melt deposition, among many other techniques. Se and/or S are also expected to behave similarly.

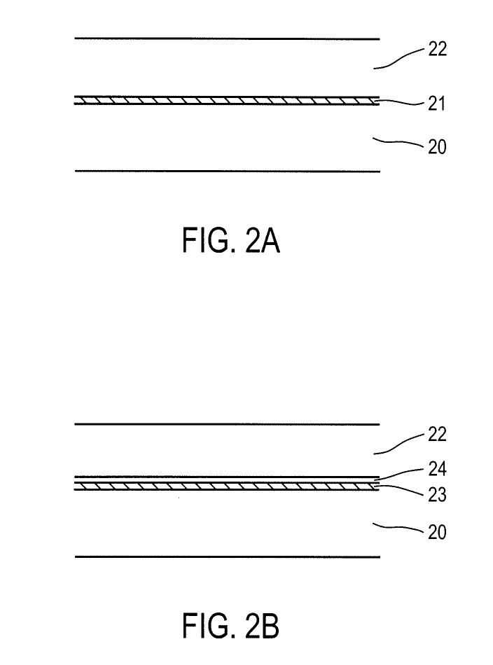

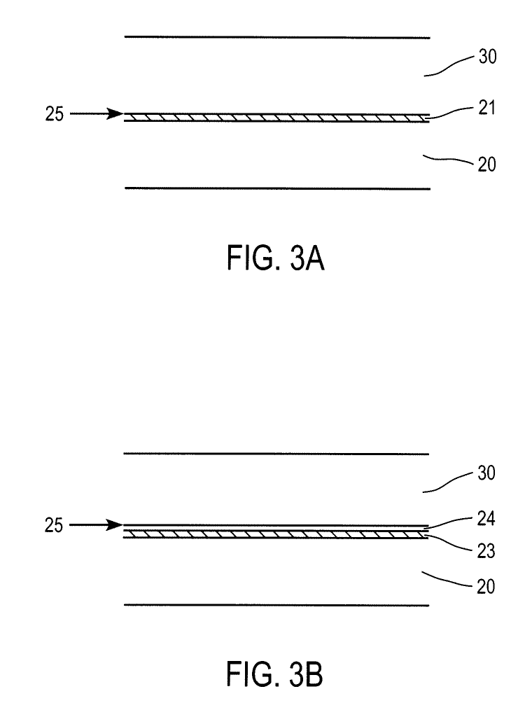

The preferred embodiments of the present invention are shown in FIGS. 2A and 2B. In FIG. 2A, a preferred contact layer 21 is deposited on a substrate 20. A metallic precursor layer 22 is then deposited over the preferred contact layer 21. The substrate 20 is a glass substrate or a conductive or insulating sheet or foil. The preferred contact layer 21 may have a thickness of 50-1000 nm and comprises at least one of the elements in the preferred group of Ru, Rh, Ir, Os, Zr, Hf and Re. The contact layer 21 most preferably comprises at least one of Ru, Ir and Os. It should be noted that preferred contact layer may be made of nitrides or other compounds of the elements of the preferred group or it may be made of alloys comprising at least one of the elements in the preferred group. For the case of Ru, Ir and Os, the preferred contact layer may be an oxide of these materials because these oxides are highly conductive, unlike oxides of many other materials. Oxides of Mo, Ta, Ti, W, etc., for example, are either high resistivity (>100 ohm-cm) or insulating depending on their composition. RuO₂, on the other hand, has a resistivity of much lower than 0.1 ohm-cm, typically in the range of 10⁻³-10⁻⁴ ohm-cm. The metallic precursor layer 22 comprises Cu, In and Ga and optionally Se and/or S and/or Te. The metallic precursor layer may be deposited by various techniques such as PVD, CVD techniques, but is preferably electroplated on the preferred contact layer 21. The metallic precursor layer may be in the form of alloys, or mixtures of Cu, In, Ga and optionally a Group VIA material or it may be in the form of metallic stacks such as those described previously. The structure of the FIG. 2A may be converted into the preferred structure shown into FIG. 3A after the formation of a CIGS(S) compound layer. In FIG. 3A the CIGS(S) layer 30 is formed over the preferred contact layer 21 and the preferred contact layer 21 forms a well adhering electrical contact to the CIGS(S) layer 30. It should be noted that part of the preferred contact layer 21 right at the interface 25 with the CIGS(S) layer 30 may be in the form of a selenide, and/or sulfide since certain degree of reaction between the preferred contact layer 21 and Group VIA materials and even with Cu, In and Ga is possible and may form a thin interface layer. If Te was also included in the absorber, a telluride phase may also be formed in the interface layer. The structure of FIG. 3A may be used to fabricate an efficient solar cell with a structure similar to the one in FIG. 1 by depositing additional layers over the CIGS(S) absorber layer. In FIG. 2B, a nucleation layer 24 is deposited on a contact layer 23, which is previously deposited on a substrate 20. A metallic precursor layer 22 is then deposited over the nucleation layer 24. The substrate 20 is a glass substrate or a conductive or insulating sheet or foil. The contact layer 23 may have a thickness of 100-1000 nm and comprises a conductive material, such as Mo, Ta, W, Ni, Cu, Ti, Cr etc. Practically any conductive material may be used as a contact layer in this case because diffusion barrier aspects of the nucleation layer 24 protects the contact layer from reacting with the metallic precursor layer 22 and/or with Group VIA materials. The nucleation layer may have a thickness of 1-300 nm, preferably 5-100 nm and comprises at least one of the elements in the preferred group of Ru, Rh, Ti, Os, Zr, Hf and Re. The nucleation layer most preferably comprises at least one of Ru, Ir and Os. It should be noted that the nucleation layer may be made of nitrides or other compounds of the elements of the preferred group or it may be made of alloys comprising at least one of the elements in the preferred group. The metallic precursor layer 22 comprises Cu, In and Ga and optionally Se and/or S and/or Te. The metallic precursor layer is preferably electroplated on the nucleation layer 24. The metallic precursor layer may be in the form of alloys, or mixtures of Cu, In, Ga and optionally a Group VIA material, or it may be in the form of metallic stacks such as those described previously. The structure of the FIG. 2B may be converted into the preferred structure shown into FIG. 3B after the formation of a CIGS(S) compound layer. In FIG. 3B the CIGS(S) layer 30 is formed over the nucleation layer 24. It should be noted that part of the nucleation layer 24 right at the interface 25 with the CIGS(S) layer 30 may be in the form of a selenide and/or sulfide since certain degree of reaction between the nucleation layer 24 and Group VIA materials and even with Cu, In and Ga is possible and may form an interface layer. If the thickness of the nucleation layer is small (such as 1-50 nm), substantially all of the nucleation layer may be converted into a selenide, and/or sulfide during the formation of the CIGS(S) layer. If Te was also included in the absorber, a telluride phase may also be formed in the nucleation layer. The structure of FIG. 3B may be used to fabricate an efficient solar cell with a structure similar to the one in FIG. 1 by depositing additional layers, such as transparent conductive or semiconductive layers, over the CIGS(S) absorber layer.

The metallic precursor stack layers of the present invention may also comprise small amounts of dopants such as Na, K, Li, Sb, P etc. Dopants may be plated along with the layers or sublayers of the stack or may be plated as a separate micro-layer. For example, dopants such as K and Na may be included into the electroplating electrolytes of Cu, and/or In and/or Ga. Up to about 1% (molar) of dopants may be included into the precursor. The overall Cu/(In+Ga) molar ratio in the metallic precursor stack may be in the range of 0.7-1.2, preferably in the range of 0.8-1.0. The Ga/(Ga+In) molar ratio may be in the range of 0.01-0.99, preferably in the range of 0.1-0.4.

Reaction of metallic precursors (such as the ones shown in FIGS. 2A and 2B) with Group VIA materials may be achieved various ways. In one case the precursor layer is exposed to Group VIA vapors at elevated temperatures. These techniques are well known in the field and they involve heating the precursor layer to a temperature range of 350-600° C. in the presence of at least one of Se vapors, S vapors, and Te vapors provided by sources such as solid Se, solid S, solid Te, H₂Se gas, H₂S gas etc. for periods ranging from 5 minutes to 1 hour. In another case a layer or multi layers of Group VIA materials are deposited on the precursor layer and the stacked layers are then heated up in a furnace or in a rapid thermal annealing furnace and like. Group VIA materials may be evaporated on, sputtered on or plated on the precursor layer. Alternately inks comprising Group VIA nano particles may be prepared and these inks may be deposited on the precursor layers to form a Group VIA material layer comprising Group VIA nano particles. Dipping, spraying, doctor-blading or ink writing techniques may be employed to deposit such layers. Reaction may be carried out at elevated temperatures for times ranging from 1 minute to 30 minutes depending upon the temperature. As a result of reaction, the Group IBIIIAVIA compound is formed from the precursor and the structures shown in FIGS. 3A and 3B may be obtained.

Although certain embodiments of the present invention have been described using electrodeposited precursor layers and reaction of these layers with a Group VIA material, they are generally applicable to structures obtained by various other techniques such as evaporation, sputtering etc. For example, present inventor recognized certain unique features of Ru, Ir and Os (i.e. the most preferred materials) that make these materials especially attractive as contact materials or nucleation layers in Group IBIIIAVIA compound solar cell structures.

As reviewed before, the standard contact material for a CIGS(S) type solar cell is Mo. A wide range of materials have also been evaluated by researchers as possible contact layers to CIGS(S) type solar cells. These materials are Au, W, Ta, Nb, Cr, V, Ti, Mn, Pd, Pt, TiN, Ni, Ni—P and ZrN. Motivations for identifying a new contact layer for the CIGS(S) solar cell changed from research group to research group and included; i) improving adhesion of the CIGS(S) layer to the substrate in processes that involve fabrication of a highly Cu-rich layer with Cu/(In+Ga) ratio of higher than 1.6 followed by a wet etching step, and ii) increasing the optical reflection of the back contact. Some of the materials listed above were found to be unsuitable as contact layers because they reacted extensively with the Group VIA materials and/or with Cu, In, Ga species. Some reportedly performed well. Mo, however, is the most widely used contact material in commercial CIGS(S) solar cell structures.

One important aspect to be taken into consideration in selecting a contact material for Group IBIIIAVIA compound films such as CIGS(S) layers and solar cells is the long term stability. Solar cells need to be built to last at least 20 years and possibly 30 years. They get as hot as 60-80 C during operation in desert areas. Therefore, short term chemical interactions between the contact layer and the absorber layer components, i.e. Cu, In, Ga, Se, S etc. during the formation of the CIGS(S) layer as well as the long term (20-30 years) interactions between the contact layer and the already formed CIGS(S) layer need to be taken into consideration. Table 1 provides information about interactions between six possible contact materials (Ru, Ir, Os, Rh, Pt, Pd) and Cu, In, Ga, Se and S. The solubilities and possible reaction products are listed in this table. Information for reaction products with Se and S was obtained from the publication titled “Platinum Group Metal Chalcogenides” by S. Dey and V. Jain (Platinum Metals Review, vol: 48, p: 16, 2004). Information about solubilities and interactions between the six materials and Cu, In and Ga were obtained from the available binary phase diagrams which show the various new materials phases formed as a result of chemical interaction between two materials.

Data in Table 1 point out to important differences between a first group of materials comprising Ru, Os, Ir and a second group of materials comprising Rh, Pd and Pt, in terms of their interactions with Cu, In, Ga, Se and S, despite the fact that they all belong to a group of materials known as “platinum group metals”. These differences can be summarized as follows: A) Ru, Os, and Ir do not have much solubility in Cu, whereas Rh, Pt and Pd have continuous solid solutions with Cu, B) there is very small solubility of Ru, Os and Ir in In whereas several Pd—In and Pt—In compounds exist suggesting extensive reactivity between these elements, C) although, data for Ga is lacking, it can be assumed that situation would be similar to the case of In, D) reacting with selenium, Ru, Os and Ir form a well defined single phase selenide, whereas Rh, Pt and Pd form multiple selenide phases with different crystalline structures, E) reacting with sulfur, Ru and Os form a well defined single phase sulfide, Ir forms two well defined sulfide phases with similar crystal structure, whereas Rh, Pt and Pd form multiple sulfide phases with different crystalline structures.

The unit cell lattice parameters for cubic RuSe₂ and RuS₂ are a=5.93 Å and a=5.61 Å, respectively. Corresponding cell parameters for cubic OsSe₂ and OsS₂ are a=5.95 Å and a=5.62 Å. The solar cell absorbers of CuInSe₂, CuGaSe₂, CuInS₂, and CuGaS₂ have tetragonal structures with unit cell parameters of around (a=5.78 Å, c=11.57 Å), (a=5.61 Å, c=11.01 Å), (a=5.52 Å, c=11.08 Å) and (a=5.36 Å, c=10.49 Å), respectively. For absorbers containing Al and/or Te, the “a” values vary between about 5.3 Å and 6.1 Å. Therefore, Ru(Se,S)₂ and Os(Se,S)₂ have excellent lattice match to CIGS(S) material (typically less than 10% lattice mismatch), and in general Ru(Se,S,Te)₂ and Os(Se,S,Te)₂ have very good lattice match to Group IB IIIAVIA materials comprising at least one of Cu and Ag as Group IB material, at least one of In, Ga, Al as the Group IIIA material and at least one of Se, S and Te as the Group VIA material. For example, for the case of RuSe₂ and CuInSe₂ the lattice mismatch is only (5.93-5.78)/5.93=2.5%.

The lattice match between Group IBIIIAVIA absorbers and IrSe₂ is also good. IrSe₂ has orthorhombic structure with a=20.95 Å, b=5.94 Å and c=3.74 Å. Therefore, the base of the unit cell matches well, in one crystalline direction, to the base of the tetragonal unit cell of the absorber. In the other direction (along a) the mismatch is about (22.44-20.95)/20.95=7%, for the case of CuGaSe₂, where 22.44 Å is four times the “a” value of the CuGaSe₂ absorber. IrS₂ and Ir₂S₃ have unit cell parameters of (a=19.79 Å, b=5.62 Å, c=3.56 Å) and (a=8.48 Å, b=6.01 Å, c=6.16 Å), respectively. The discussion above demonstrates that the group of materials, comprising Ru, Os and Ir offer unique benefits as contact layers, nucleation layers or interfacial layers making electrical as well as physical contact to Group IBIIIAVIA materials. One of these benefits, as reviewed before is the fact that chemical interactions between Cu, In, Ga and the group comprising Ru, Os and Ir are quite limited. Therefore, while growing, for example, a CIGS(S) compound layer on a Ru surface, the Ru layer does not extensively react with the elements of the compound and does not negatively influence the composition of the compound. If a contact layer interacted with at least one of Cu, In and Ga, it would form intermetallics by tying down at least part of the available Cu, In or Ga. This would, therefore, reduce the amount of that element in the absorber layer and thus deteriorate the composition and electrical properties of the absorber. This lack of interaction is also good for long term stability of the solar cell structure after the CIGS(S) layer is formed. Solar cells operating at elevated temperatures for 20-30 years need to be stable. This requires that the interface between the absorber layer and the contact or nucleation layer be stable.

The other benefit of using contact layers or interfacial layers comprising Ru, Os and Ir relates to how these materials interact with the Group VIA elements such as Se, S and Te. During the deposition of a Group IBIIIAVIA material on a surface comprising Ru, and/or Os and/or Ir, an interfacial layer forms between the Group IBIIIAVIA absorber and the Ru, and/or Os and/or Ir. This interfacial layer comprises at least one of a selenide, sulfide and telluride of Ru, and/or Os and/or Ir, which as we showed have good lattice match to the Group IBIIIAVIA layer. Lattice match reduces structural and electrical imperfections at the contact/absorber interface and it reduces strain and stress at that location. This may help grain growth and produce Group IBIIIAVIA absorber layers with columnar, large grains, which are superior for solar cell fabrication. In contrast, contact layers made of only Rh, Pt and Pd, when reacted with Se or S, or even Te, produce multi-phase interfacial layers as can be seen from Table 1. It would be appreciated that lattice mismatch between such interfacial layers and the Group IBIIIAVIA absorber layers grown over them would be large and even un-defined (because there are so many different possible lattice structures) because the interfacial layer may have various chemical compositions and crystalline structures.

Additionally, present inventor found that reaction of materials from the most preferred group with Group VIA materials was much more limited than reaction of prior art Mo layers with the same Group VIA materials. For example, when a sputter deposited Mo layer and a sputter deposited Ru layer on glass substrates were selenized in H₂Se containing atmosphere for 1 hour at 500 C, a Mo-selenide layer of about 200 nm thickness formed on the surface of the Mo layer, whereas the thickness of Ru-selenide layer on the Ru layer was about 20 nm. This shows that much thinner contact layers of materials from the most preferred list may be used in the solar cell structures, compared to the prior art Mo contact layers. For example, 500-700 nm Mo layers, which are typical for prior art devices, may be replaced by 50-70 nm thick Ru layers and still protect the substrate or base from reactive environments comprising Group VIA materials. Furthermore, use of contact layers comprising at least one of Ru, Ir and Os allows the reaction temperature to be higher. For example, in two-stage processes that involve reacting a precursor layer comprising Cu, In and Ga with H₂Se and/or H₂S the reaction temperature is typically kept below 500 C. This is because, above this temperature, for example at temperatures close to 600 C, the Mo contact layer reacts excessively with the Se and/or S and the film adhesion to the substrate also worsens. It should be appreciated that use of the more inert group of materials from the most preferred group allows the reaction temperature to be close to, even higher than 600 C. Consequently, Cu(In,Ga)(Se,S)₂ layers, or more generally Group IBIIIAVIA compound layers may be grown with larger grain size and better electrical and optical properties in shorter process times. This way the quality of the films may be improved while the throughput of the process is increased. This is important for RTP-type processes where substrates are processed one at a time. As an example, the reaction time for the formation of good quality Cu(In,Ga)Se₂ layer through reaction of a Cu(In,Ga) precursor with H₂Se gas at 450 C may be 45-90 minutes, whereas, at a reaction temperature of 575 C, this may be achieved in 10-20 minutes.

Interaction of contact materials and oxygen and water vapor is also important for long term reliability of thin film materials. The standard prior-art contact of CIGS solar cells is Mo. When prior-art cells are exposed to humidity and/or oxygen, especially at elevated temperatures, a reaction takes place at the Mo/C IGS absorber that causes instabilities. Same is true for monolithically integrated CIGS modules built on glass substrates. In such structures, adjacent solar cells are connected in series by forming a ZnO/Mo interface, i.e. ZnO transparent layer or top electrode of one cell is shorted to the Mo contact layer or bottom electrode of the next cell. When the ZnO/Mo connection is exposed to moisture and/or oxygen for long periods of time, the resistance of the interface increases reducing the fill factor of the module, which is not acceptable in solar modules which need to have 20-30 year lifetime. Sensitivity of Mo to water vapor and oxygen is partly due to its high reactivity with oxygen, which is a Group VIA element just like Se and S. Molybdenum does not form a protective oxide layer on its surface. Therefore as it gets oxidized, the surface oxide grows and introduces high resistance at the Mo/CIGS and/or the ZnO/Mo interfaces. This contributes to the above mentioned instabilities in solar cells and modules employing Mo contacts. Use of a material from the preferred group, especially at least one of Ru, Ir and Os in place of Mo or on the surface of Mo in a CIGS type solar cell or module eliminates this problem. For example, if the structure of a CIGS solar cell is Mo/Ru/CIGS or Ru/CIGS, exposure of this structure to water vapor (H₂O) and/or oxygen would result in a very thin (compared to a Mo layer) oxide layer on the Ru surface at the Ru/CIGS interface, just as reaction of Ru with H₂Se and H₂S results in a very thin (compared to a Mo layer) selenide or sulfide layer as described earlier. It should be noted that chemically, H₂Se, H₂S and H₂O belong to the same group, as Se, S and O belong to the same Group VIA, and reactivity of Ru, Ir and Os is much less with these materials compared to reactivity of many other common metals such as Mo, W, Ta, Ti, Ni etc.

Thin nature of oxides formed on Ru, Ir and Os surfaces as well as their high electrical conductivity yield interfaces) with these materials (such as Ru/CIGS interface or ZnO/Ru interface that are stable in moisture and/or oxygen containing environment. This means longer lifetime for un-packaged or packaged solar cells or modules, wherein the packaging may not provide absolute hermetic sealing.

It should be noted that the contact layers comprising at least one of Ru, Os and Ir may have these materials in the form of alloys, compounds or mixtures. For example, Ru may be in the form of Ru, Ru-oxide, Ru-selenide, Ru-sulfide, Ru-telluride, Ru-sulfo-selenide, Ru-sulfo-telluride, Ru-seleno-telluride, Ru-M alloys or mixtures where M is a metal or a Group IVA material, Ru-nitride, Ru-carbide etc. Similar arguments are valid for Os and Ir also. Although, formation of C-GroupVIA compound(s) at the interface between a “C” contact layer (where C may comprise Ru and/or Ir and/or Os) and a Group IBIIIAVIA absorber film may happen during the growth of the Group IBIIIAVIA absorber layer on the surface of the “C” layer, it is also possible to deposit a C-GroupVIA compound layer on a substrate and then grow the Group IBIIIAVIA compound layer over it. For example, a Ru(S,Se)₂ layer may first be grown on a conductive surface such as a Mo, Ti, Cr, Al, Ta, W, Ni etc surface. A high quality Cu(In,Ga)(Se,S)₂ absorber layer may then be grown on the Ru(S,Se)₂ layer. Such an approach still benefits from the excellent lattice match between Ru(S,Se)₂ and Cu(In,Ga)(Se,S)₂ as described above. It should be noted that when a Group IBIIIAVIA absorber layer is grown on the commonly used Mo contact layers, a Mo-Group VIA interface forms between the Mo layer and the Group IBIIIAVIA absorber. Since Mo forms many different sulfide, telluride and selenide phases, each with their own different crystalline structure, the lattice mismatch between these Mo-Group VIA interface layers and the Group IBIIIAVIA absorber layers is large. For example, during growth of a Cu(In,Ga)Se₂ absorber on a Mo surface, phases such as MoSe₂ (JCPDS diffraction file 29-914), Mo₃Se₄ (JCPDS diffraction file 24-772), Mo₉Se₁₁ (JCPDS diffraction file 40-908), Mo₁₅Se₁₉ (JCPDS diffraction file 39-786), etc., may form at the Mo/Cu(In,Ga)Se₂ interface. These phases have crystalline structures of hexagonal, rhombohedral, orthorhombic, and hexagonal, respectively. Some of the other attractive features of Ru, Ir and Os as contact layers to solar cells using Group IBIIIAVIA absorber films include better wetting characteristics of these materials by the Group IB and Group IIIA elements. Copper, for example, wets Ru, Ir and Os surfaces well with small contact angle. This improves nucleation of Cu on such contact layer surfaces, allowing good coverage by thin Cu layers formed by a variety of techniques such as electroplating, chemical vapor deposition, atomic layer deposition, evaporation, sputtering, etc. For example, Cu layers as thin as 10 nm can be coated on Ru surface with excellent coverage, whereas this cannot be achieved on materials such as Mo, Ti, Ta etc. This is because the density of nucleation centers for Cu on Ru is much larger than on the other materials cited. Situation is similar for In and Ga also, i.e. nucleation of Ga and In on Ru, Ir and Os is better than their nucleation on prior art contact materials such as Mo. Good wetting plays a role even after the deposition of precursors or layers comprising at least one of Cu, In and Ga on the contact films or layers. For example, as described in U.S. Patent Application Publication Nos. 2005/0202589 and 2006/0121701 mentioned previously, after precursors including Cu, In and/or Ga, and optionally a Group VIA material are deposited on a substrate, they may be heated up to enhance alloying or reaction between the elements. If the wetting characteristics of the substrate surface or the contact layer are not good, morphology of the precursor layer deteriorates during heating. For example, low melting phases such as In and Ga may give rise to “balling” phenomenon which in turn introduces compositional non-uniformity in the plane of the film. This compositional non-uniformity, i.e. variation in the Cu/(In+Ga) and Ga/(Ga+In) ratios in the plane of the film, carries over to the Group IBIIIAVIA compound layer after the reaction is completed and the compound is formed. Solar cell efficiencies are low on such non-uniform compound layers because efficiency is a function of composition. Presence of a material from the most preferred list on the substrate surface minimizes or eliminates problems giving rise to compositional micro-scale non-uniformities, such as “balling”, because nucleation and wetting are superior.

Solar cells may be fabricated on the compound layers of the present invention using materials and methods well known in the field. For example a thin (<0.1 microns) CdS layer may be deposited on the surface of the compound layer using the chemical dip method. A transparent window of ZnO may be deposited over the CdS layer using MOCVD or sputtering techniques. A metallic finger pattern is optionally deposited over the ZnO to complete the solar cell. ZnO layers alloyed or doped with In are especially suited for CIGS(S) solar cells. Such In—Zn—O (IZO) transparent conductors may be deposited by various techniques such as sputtering and may yield amorphous layers as opposed to ZnO films which are typically polycrystalline in nature. CIGS(S) solar cells are moisture sensitive and amorphous layers are much better moisture barriers than polycrystalline layers since they don't have grain boundaries through which species may diffuse. Therefore a CIGS(S) solar cell structure comprising amorphous IZO as at least part of its transparent conductive window layer is attractive for moisture resistance. Such a structure may be substrate/contact layer/CIGS(S)/CdS/IZO, with CdS layer being optional, or it may have ZnO or other transparent conductive oxides such as In—Sn—O either under or over the IZO layer.

| | Cu | In | Ga | Se | S |
|---|---|---|---|---|---|
| Ru | Negligible solid | 0.01% solubility in | | RuSe₂ (cubic) phase | RuS₂ (cubic) phase |
| | solubility of Ru in | In at 400 C. In₃Ru | | reported. | reported. |
| | Cu. | formed at 850 C. | | | |
| | | after 300 hrs. | | | |
| Os | Negligible solid | 0.03% Os solubility | | OsSe₂ (cubic) phase | OsS₂ (cubic) phase |
| | solubility of Os in | in In at 400 C. | | reported. | reported. |
| | Cu. | | | | |
| Ir | 0.5% Ir is soluble in | 0.02% Ir solubility | | IrSe₂ (orthorombic) phase | IrS₂ (orthorombic) |
| | Cu at 700-850 C. | in In at 400 C. In₃Ir, | | reported. | Ir₂S₃(orthorhombic) |
| | | In₂Ir phases | | | phases reported. |
| | | reported. | | | |
| Rh | Continuous solid | InRh phase reported. | | RhSe₂ (orthorhombic), | RhS₂ (cubic), Rh₂S₃ |
| | solution between Rh | | | Rh₃Se₈ (rhombohedral), | (orthorombic), |
| | and Cu. | | | RhSe₂₊ₓ (cubic), Rh₂Se₃ | Rh₁₇S₁₅ (cubic) |
| | | | | (orthorombic), Rh₃Se₄ | Rh₃S₄ (monoclinic) |
| | | | | (hexagonal) phases reported. | phases reported. |
| Pt | Continuous solid | PtIn₂, Pt₂In₃, Pt₃In₇ | PtGa, | PtSe₂ (hexagonal), Pt₅Se₄ | PtS₂ (hexagonal), |
| | solution between Pt | phases reported. | Pt₂Ga₃, | (monoclinic) phases | PtS (tetragonal) |
| | and Cu. | | PtGa₂, | reported. | phases reported. |
| | | | Pt₃Ga₇ | | |
| | | | phases | | |
| | | | reported. | | |
| Pd | Continuous solid | Pd-rich solid | PdGa, | PdSe (tetragonal) Pd₁₇Se₁₅ | PdS (tetragonal) |
| | solution between Pd | solution with 20% | Pd₂Ga, | (cubic) Pd₇Se₄ | PdS₂ (orthorombic) |
| | and Cu. | In, Pd₃In, PdIn, | Pd₃Ga, | (orthorombic), Pd₃₄Se₁₁ | Pd₁₆S₇ (cubic) |
| | | Pd₂In₃, Pd₂In, Pd—In | Pd₃Ga₇ | (monoclinic), Pd₇Se | Pd_{2.8}S(cubic) |
| | | with 75% In phases | phases | (monoclinic), Pd₄Se | Pd₃S(orthorhombic) |
| | | reported. | reported. | (tetragonal), Pd_{4.5}Se | Pd₄S (tetragonal) |
| | | | | (tetragonal), PdSe₂ | phases reported. |
| | | | | (orthorhombic) Pd_{2.5}Se, | |
| | | | | Pd₃Se, Pd₈Se phases | |
| | | | | reported. | |

Although the present invention is described with respect to certain preferred embodiments, modifications thereto will be apparent to those skilled in the art. For example, the contact layers or nucleation layers of the present invention may be used to form contacts to various important semiconducting layers belonging to the Group JIB VIA materials such as CdTe, ZnTe, CdSe, and their alloys, etc.

1. A substrate type thin film solar cell, comprising:
a sheet-shaped substrate;
CIGS absorber layer disposed over the sheet shaped substrate, wherein the absorber layer includes copper (Cu), indium (In), gallium (Ga) and selenium (Se);
an ohmic contact layer disposed between the sheet shaped substrate and the CIGS absorber layer, wherein the ohmic contact layer includes a ruthenium layer (Ru) having a thickness in the range of 1-300 nanometers; and
a transparent conductive layer disposed on the absorber layer and configured so that light enters the solar cell through the transparent conductive layer.

2. The solar cell according to claim 1 wherein the transparent conductive layer comprises at least one of cadmium sulfide (CdS), zinc oxide (ZnO), indium tin oxide (ITO) and indium zinc oxide (IZO).

3. The solar cell according to claim 1 wherein the Ru layer at least partially includes one of a selenide of Ru or a sulfide of Ru.

4. (canceled)

5. The solar cell according to claim 1 wherein the ohmic contact layer includes a plurality of layers, with at least one of a lower ohmic contact layer and an upper ohmic contact layer including the Ru layer, and wherein the upper ohmic contact layer is sandwiched between the absorber layer and the lower ohmic contact layer.

6-12. (canceled)

13. The solar cell according to claim 1 wherein the substrate is one of a stainless steel sheet and an aluminum sheet.

14. The solar cell according to claim 1 wherein the substrate is an insulating sheet.

15-19. (canceled)

20. The solar cell according to claim 2 wherein the transparent conductive layer is a CdS/ZnO stack.

21-29. (canceled)

30. A method of making a solar cell comprising the steps of:
forming an ohmic contact layer including a ruthenium layer (Ru) having a thickness in the range of 1-300 nanometers over a top surface of a sheet-shaped substrate;
forming CIGS absorber layer on the ohmic contact layer, the step of forming the absorber layer including the steps of:
depositing a set of distinct layers on a top surface of the ohmic contact layer, the set of distinct layers including at least four layers, with two of the layers being a pair of non-adjacent layers made of one of Cu, In and Ga, and the other two layers being made of the remaining two of the Cu, In and Ga; and
treating the set of distinct layers to form the CIGS absorber layer; and
forming a transparent conductive layer on the CIGS absorber layer.

31. (canceled)

32. The method according to claim 30 wherein the step of depositing the set of distinct layers deposits them in the order Cu/In/Cu/Ga or Cu/Ga/Cu/In, such that the pair of non-adjacent layers is Cu.

33. The method according to claim 32 wherein the step of depositing is performed with electrodeposition.

34. The method according to claim 30 wherein the step of depositing is performed with electrodeposition.

35. The method according to claim 34 wherein the step of depositing includes the step of depositing a Group VIA material, and wherein the step of treating causes the Group VIA material to react with Cu, In and Ga and the ohmic contact layer thereby forming an interface layer between the ohmic contact layer and the CIGS absorber layer, the interface layer comprising a compound of Ru with the Group VIA material.

36. (canceled)

37. The method according to claim 35 wherein top surface of the sheet-shaped substrate comprises Mo.

38-48. (canceled)

49. A method of making a solar cell that converts light to electrical energy comprising the steps of:
forming an ohmic contact layer comprising a ruthenium layer (Ru) having a thickness in the range of 1-300 nanometers over on a sheet-shaped substrate;
forming a semiconductor absorber layer on a surface of the ohmic contact layer, wherein the semiconductor absorber layer comprises copper (Cu), indium (In), gallium (Ga) and selenium (Se); and
forming transparent conductive layer on the absorber layer for the light to enter the solar cell.

50. (canceled)

51. The method of claim 49 wherein the semiconductor absorber layer is a Group IBIIIAVIA compound layer.

52. The method of claim 51 wherein the Group IBIIIAVIA absorber layer is formed while a compound interface layer forms on the surface of the ohmic contact layer, the compound interface layer including at least one of a sulfide and a selenide of Ru.

53-54. (canceled)

55. The method according to claim 49 wherein the step of forming the semiconductor absorber layer is carried out using at least one of electrodeposition, evaporation, sputtering and nano-particle deposition.

56-62. (canceled)

63. A method of forming a Cu(In,Ga)(Se,S)₂ absorber layer comprising the steps of:
applying, on a sheet-shaped substrate, a conductive layer comprising a ruthenium layer (Ru) having a thickness in the range of 1-300 nanometers;
electrodepositing discrete layers in sequence to farm a precursor stack over the conductive layer, each discrete layer substantially comprising one of Cu, In and Ga, and wherein at least one discrete layer substantially comprising Cu is electrodeposited using a Cu electrolyte over another discrete layer substantially comprising one of In and Ga; and
reacting the precursor stack with at least one of Se and S.

64. The method according to claim 63, wherein the step of electrodepositing is carried out with the sequence selected from Ga/Cu/In, Ga/Cu/In/Ga, Ga/Cu/In/Cu, In/Cu/Ga, In/Cu/Ga/In, In/Cu/Ga/Cu, In/Ga/Cu, In/Ga/Cu/In, In/Ga/Cu/Ga, Ga/In/Cu, Ga/In/Cu/In, Ga/In/Cu/Ga, Cu/Ga/Cu/In, Cu/Ga/Cu/In/Ga, Cu/Ga/Cu/In/Cu, Cu/In/Cu/Ga, Cu/In/Cu/Ga/In, Cu/In/Cu/Ga/Cu, Cu/In/Ga/Cu, Cu/In/Ga/Cu/In, Cu/In/Ga/Cu/Ga, Cu/Ga/In/Cu, Cu/Ga/In/Cu/In, and Cu/Ga/In/Cu/Ga.

65-67. (canceled)

68. The method according to claim 64 wherein the Cu electrolyte comprises a Cu complexing agent.

69. The method according to claim 68 wherein the Cu complexing agent is at least one of TEA, EDTA, NTA, tartaric acid, citrate and acetate.

70. The method according to claim 69 wherein the pH of the Cu electrolyte is above 3.0 and Cu electroplating is carried out at a current density in the range of 0.1-30 mA/cm2.

71-72. (canceled)

73. The method according to claim 63 wherein the sheet-shaped substrate comprises a conductive foil.

74-76. (canceled)

77. A superstrate type thin film solar cell, comprising:
a sheet-shaped transparent substrate;
a transparent conductive layer disposed on the sheet shaped transparent substrate and configured so that light may enter the solar cell through the transparent conductive layer;
a CIGS absorber layer disposed on the transparent conductive layer, wherein the absorber layer includes copper (Cu), indium (In), gallium (Ga) and selenium (Se); and
an ohmic contact layer disposed on the absorber layer, wherein the ohmic contact layer includes a ruthenium layer (Ru) having a thickness in the range of 1-300 nanometers.

78. The solar cell according to claim 77, wherein the absorber layer is a Group IBIIIAVIA compound layer.

79. The solar cell according to claim 77 wherein the sheet-shaped transparent substrate is glass.

80. The solar cell according to claim 5, wherein the lower ohmic contact layer is a molybdenum (Mo) layer formed on the sheet shaped transparent substrate.

81. The solar cell according to claim 80, wherein the Mo layer has a thickness in the range of 100-1000 nanometers.

83. The solar cell according to claim 5, wherein the Ru layer has a thickness in the range of 1-20 nanometers.

84. The solar cell according to claim 5, wherein the Ru layer has a thickness in the range of 2-6 nanometers.

85. The solar cell according to claim 5, wherein the lower ohmic contact layer is a chromium (Cr) layer formed on the sheet shaped substrate.

86. The solar cell according to claim 85, wherein the Cr layer has a thickness in the range of 100-1000 nanometers.

87. The solar cell according to claim 5, wherein the lower ohmic contact layer is a copper (Cu) layer formed on the sheet shaped substrate.

88. The solar cell according to claim 87, wherein the Cu layer has a thickness in the range of 100-1000 nanometers.

89. The solar cell according to claim 5, wherein the lower ohmic contact layer is one of a tantalum (Ta) layer, tungsten (W) layer, nickel (Ni) layer, aluminum (Al) layer, and titanium (Ti) layer formed on the sheet shaped substrate.

90. The solar cell according to claim 5, wherein the Ru layer has a thickness in the range of 2-100 nanometers.

91. The solar cell according to claim 5, wherein the Ru layer has a thickness in the range of 1-50 nanometers.

92. The solar cell according to claim 1, wherein the Ru layer has a thickness in the range of 2-100 nanometers.

93. The solar cell according to claim 1, wherein the Ru layer has a thickness in the range of 1-50 nanometers.

94. The method according to claim 30, wherein the sheet-shaped substrate comprises a stainless steel foil.

95. The method according to claim 49, wherein the sheet-shaped substrate comprises a stainless steel foil.

96. The method according to claim 73, wherein the sheet-shaped substrate comprises a stainless steel foil.

97. The method according to claim 49 wherein the step of forming the semiconductor absorber layer is carried out using electrodeposition.
